(19) United States
(12) Patent Application Publication
(10) Pub. No.: US 2026/0334041 A1
(43) Pub. Date: Oct. 22, 2026

(54) DISPLAY DEVICE AND ELECTRONIC DEVICE COMPRISING THE SAME

(71) Applicant: Samsung Display Co., LTD., Yongin-si (KR)

(72) Inventors: Seong Yong HWANG, Yongin-si (KR); Chan Young KIM, Yongin-si (KR); Eun Je JANG, Yongin-si (KR); Chang Wook KIM, Yongin-si (KR); Jin Su LEE, Yongin-si (KR); Choong Youl IM, Yongin-si (KR)

(21) Appl. No.: 19/557,789

(22) Filed: Mar. 5, 2026

(30) Foreign Application Priority Data
Apr. 22, 2025 (KR) 10-2025-0052377

(51) Int. Cl. H10K 59/38; H10K 59/122; H10K 59/80

(52) U.S. Cl. CPC H10K 59/38; H10K 59/122; H10K 59/8792

(57) ABSTRACT

A display device includes: a lower substrate; pixel electrodes disposed on the lower substrate; a pixel defining layer which defines pixels overlapping the pixel electrodes on the lower substrate; light-emitting portions disposed on the pixel electrodes; light-shielding portions disposed above the pixel defining layer; and a color filter layer including a first color forming portion, a second color forming portion, and a third color forming portion, which are positioned above the light-emitting portions to transmit lights of different colors. The first color forming portion, the second color forming portion and the third color forming portion include a first color filter, a second color filter and a third color filter, respectively. In the light-shielding portion, the first color forming portion, the second color forming portion, and the third color forming portion overlap one another in a thickness direction.

This application claims priority to Korean Patent Application No. 10-2025-0052377, filed on Apr. 22, 2025, and all the benefits accruing therefrom under 35 U.S.C. § 119, the content of which in its entirety is herein incorporated by reference.

### BACKGROUND

### (1) Field

Embodiments of the present application relate to a display device and an electronic device including the display device, and more specifically, to a display device including color filters and an electronic device including the display device.

### (2) Description of the Related Art

An organic light-emitting device has self-emissive characteristics, and may provide wide viewing angles and high contrast performance. In addition, the organic light-emitting device may provide a high response speed and high luminance. A display device has a plurality of pixels. The plurality of pixels may emit light in different colors, and for example, color filters may be included in the pixels to improve color purity.

For example, colored light generated by a light-emitting portion of the pixel may be emitted to the outside through the color filter without a separate polarization layer.

### SUMMARY

Embodiments of the present invention provide a display device with improved luminous efficiency and side-view color characteristics.

According to an embodiment, a display device includes: a lower substrate; pixel electrodes disposed on the lower substrate; a pixel defining layer which defines pixels overlapping the pixel electrodes on the lower substrate; light-emitting portions formed on the pixel electrodes; light-shielding portions positioned above the pixel defining layer; and a color filter layer including a first color forming portion, a second color forming portion, and a third color forming portion, which are positioned above the light-emitting portions, where the first color forming portion, the second color forming portion, and the third color forming portion transmit lights of different colors. In such an embodiment, the first color forming portion, the second color forming portion and the third color forming portion include a first color filter, a second color filter and a third color filter, respectively. In such an embodiment, in the light-shielding portion, the first color filter, the second color filter, and the third color filter overlap one another in a thickness direction. In such an embodiment, a shorter separation distance between a point corresponding to an end of the pixel defining layer in the first color forming portion and either the second color filter or the third color filter of an adjacent light-shielding portion of the first color forming portion is different from a shorter separation distance between a point corresponding to an end of the pixel defining layer in the second color forming portion and either the first color filter or the third color filter of an adjacent light-shielding portion of the second color forming portion.

In some embodiments, a longer separation distance between the point corresponding to the end of the pixel defining layer in the first color forming portion and either the second color filter or the third color filter of the adjacent light-shielding portion of the first color forming portion may be different from a longer separation distance between the point corresponding to the end of the pixel defining layer in the second color forming portion and either the first color filter or the third color filter of the adjacent light-shielding portion of the second color forming portion.

In some embodiments, the shorter separation distance between the point corresponding to the end of the pixel defining layer in the first color forming portion and either the second color filter or the third color filter of the adjacent light-shielding portion the first color forming portion may be different from the shorter separation distance between a point corresponding to an end of the pixel defining layer in the third color forming portion and either the first color filter or the second color filter of an adjacent light-shielding portion of the third color forming portion.

In some embodiments, a longer separation distance between the point corresponding to the end of the pixel defining layer in the first color forming portion and either the second color filter or the third color filter of the adjacent light-shielding portion of the first color forming portion may be different from a longer separation distance between the point corresponding to the end of the pixel defining layer in the third color forming portion and either the first color filter or the second color filter of the adjacent light-shielding portion of the second color forming portion.

In some embodiments, the shorter separation distance between the point corresponding to the end of the pixel defining layer in the first color forming portion and either the second color filter or the third color filter of the adjacent light-shielding portion of the first color forming portion may be greater than the shorter separation distance between the point corresponding to the end of the pixel defining layer in the second color forming portion and either the first color filter or the third color filter of the adjacent light-shielding portion of the third color forming portion.

In some embodiments, the shorter separation distance between the point corresponding to the end of the pixel defining layer in the first color forming portion and either the second color filter or the third color filter of the adjacent light-shielding portion of the first color forming portion may be greater than the shorter separation distance between the point corresponding to the end of the pixel defining layer in the third color forming portion and either the first color filter or the second color filter of the adjacent light-shielding portion of the third color forming portion.

In some embodiments, the smaller one of openings defined by the second color filter or the third color filter in a pixel corresponding to the first color forming portion may have an area different from an area of the smaller one of openings defined by the first color filter or the third color filter in a pixel corresponding to the second color forming portion.

In some embodiments, the larger one of openings defined by the second color filter or the third color filter in a pixel corresponding to the first color forming portion may have an area different from an area of the larger one of openings defined by the first color filter or the third color filter in a pixel corresponding to the second color forming portion.

In some embodiments, the smaller one of openings defined by the second color filter or the third color filter in a pixel corresponding to the first color forming portion may have an area different from an area of the smaller one of openings defined by the first color filter or the second color filter in a pixel corresponding to the third color forming portion.

In some embodiments, the larger one of openings defined by the second color filter or the third color filter in a pixel corresponding to the first color forming portion may have an area different from an area of the larger one of openings defined by the first color filter or the second color filter in a pixel corresponding to the third color forming portion.

In some embodiments, the smaller one of openings defined by the second color filter or the third color filter in a pixel corresponding to the first color forming portion may have an area larger than an area of the smaller one of openings defined by the first color filter or the third color filter in a pixel corresponding to the second color forming portion.

In some embodiments, the smaller one of openings defined by the second color filter or the third color filter in a pixel corresponding to the first color forming portion may have an area larger than an area of the smaller one of openings defined by the first color filter or the second color filter in a pixel corresponding to the third color forming portion.

In some embodiments, the shorter separation distance between the point corresponding to the end of the pixel defining layer in the first color forming portion and either the second color filter or the third color filter of the adjacent light-shielding portion of the first color forming portion may be at least 1 micrometer (μm) greater than the shorter separation distance between the point corresponding to the end of the pixel defining layer in the second color forming portion and either the first color filter or the third color filter of the adjacent light-shielding portion of the second color forming portion.

In some embodiments, the light-shielding portion does not include a black matrix.

In some embodiments, the first color forming portion may transmit green light, the second color forming portion may transmit red light, and the third color forming portion may transmit blue light.

In some embodiments, light transmitted from the first color forming portion may be constructively interfered light.

According to an embodiment, a display device includes: a lower substrate; pixel electrodes disposed on the lower substrate; a pixel defining layer which defines pixels overlapping the pixel electrodes on the lower substrate; light-emitting portions disposed on the pixel electrodes; light-shielding portions disposed above the pixel defining layer; and a color filter layer including a first color forming portion, a second color forming portion, and a third color forming portion, which are positioned above the light-emitting portions, where the first color forming portion, the second color forming portion, and the third color forming portion transmit lights of different colors. In such an embodiment, the first color forming portion, the second color forming portion and the third color forming portion include a first color filter, a second color filter and a third color filter, respectively. In such an embodiment, in the light-shielding portion, the first color filter, the second color filter, and the third color filter overlap one another in a thickness direction. In such an embodiment, the smaller one of openings defined by the second color filter or the third color filter in a pixel corresponding to the first color forming portion has an area different from an area of the smaller one of openings defined by the first color filter or the third color filter in a pixel corresponding to the second color forming portion.

In some embodiments, the larger one of openings defined by the second color filter or the third color filter in the pixel corresponding to the first color forming portion may have an area different from an area of the larger one of openings defined by the first color filter or the third color filter in the pixel corresponding to the second color forming portion.

An electronic device includes: a display device; a memory; and a processor which controls an operation of the display device by executing data included in the memory. In such an embodiment, the display device includes: a lower substrate; pixel electrodes disposed on the lower substrate; a pixel defining layer which defines pixels overlapping the pixel electrodes on the lower substrate; light-emitting portions formed on the pixel electrodes; light-shielding portions positioned above the pixel defining layer; and a color filter layer including a first color forming portion, a second color forming portion, and a third color forming portion, which are positioned above the light-emitting portions, where the first color forming portion, the second color forming portion, and the third color forming portion transmit lights of different colors. In such an embodiment, the first color forming portion, the second color forming portion and the third color forming portion include a first color filter, a second color filter and a third color filter, respectively. In such an embodiment, in the light-shielding portion, the first color filter, the second color filter, and the third color filter overlap one another in a thickness direction. In such an embodiment, a shorter separation distance between a point corresponding to an end of the pixel defining layer in the first color forming portion and either the second color filter or the third color filter of an adjacent light-shielding portion of the first color forming portion is different from a shorter separation distance between a point corresponding to an end of the pixel defining layer in the second color forming portion and either the first color filter or the third color filter of an adjacent light-shielding portion of the second color forming portion.

In some embodiments, the electronic device may include a smartphone, a tablet personal computer (PC), a laptop computer, a television (TV), a desk monitor, smart glasses (e.g., virtual reality or augmented reality glasses), a head-mounted display, a smart watch, or a vehicle display.

In the display device according to embodiments, the distance between the pixel defining layer and the color filter may be different for each pixel. Accordingly, the side-view color characteristics may be improved while maintaining or improving luminous efficiency.

### BRIEF DESCRIPTION OF THE DRAWINGS

The above and other features of embodiments of the present disclosure will be more clearly understood from the following detailed description taken in conjunction with the accompanying drawings, in which:

FIG. 1 is a schematic exploded perspective view illustrating a display device according to embodiments;

FIG. 2 is a schematic plan view illustrating a circuit structure of the display device according to embodiments;

FIG. 3 is a plan view illustrating a pixel arrangement of the display device according to embodiments;

FIG. 4 is a cross-sectional view taken along line I-I′ of FIG. 3 in a thickness direction of the display device;

FIGS. 5A, 5B and 5C are partially enlarged cross-sectional views of regions A, B and C of FIG. 4, respectively;

FIGS. 6A and 6B are schematic cross-sectional views illustrating light emission angles in region B of FIG. 4 for the display devices of an embodiment and the prior art (a comparative example), respectively;

FIGS. 7A and 7B are schematic cross-sectional views illustrating light-emitting devices according to embodiments;

FIG. 8 is a block diagram of an electronic device according to an embodiment;

FIG. 9 is a set of schematic views illustrating electronic devices according to embodiments; and

FIGS. 10 and 11 are color coordinate graphs illustrating color changes according to side viewing angles for the display device of the embodiment and the comparative example, respectively.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

As used herein, the terms “placed on,” “disposed,” “overlapped,” “connected,” “coupled,” etc., are intended to include not only direct placement, overlapping, connection, or coupling of components, but also cases where another component is interposed between the components.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions illustrated in the figures but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

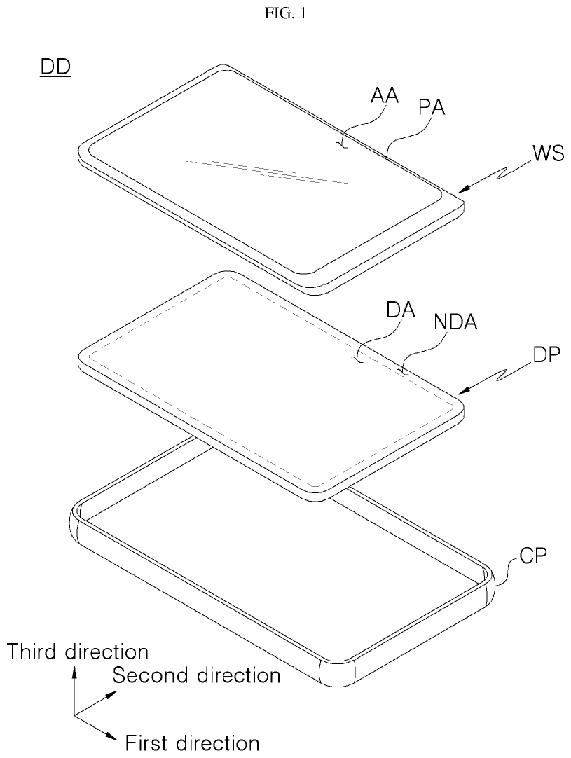

FIG. 1 is a schematic exploded perspective view illustrating a display device according to embodiments.

Referring to FIG. 1, an embodiment of a display device DD may include a window structure WS, a display panel DP, and a cover panel CP. The display device DD may be implemented as a liquid crystal display (LCD) device, an organic light-emitting diode (OLED) display device, a quantum dot light-emitting diode (QLED) display device, or the like.

In FIG. 1, a first direction and a second direction may refer to two directions that are parallel to display surfaces of the window structure WS and/or the display panel DP and intersect each other. For example, the first and second directions may be perpendicular to each other.

For example, the first direction may correspond to an X direction (row direction) of the display device DD or the display panel DP, and the second direction may correspond to a Y direction (column direction) of the display device DD or the display panel DP.

A third direction may be perpendicular to both the first and second directions. The third direction may correspond to a Z direction (thickness direction) of the display device DD or the display panel DP.

In the following drawings, the above-defined directions may be applied in the same manner.

In an embodiment of the display device DD, the cover panel CP, the display panel DP, and the window structure WS may be sequentially stacked along the third direction.

The window structure WS provides an outer display surface recognized by a user of the display device DD, and may include a transparent material film. In an embodiment, for example, the window structure WS may include glass (e.g., ultra-thin glass (UTG)), a hard coating film, a plastic film, or the like.

An outer surface of the window structure WS may include an active area AA and a peripheral area PA. The active area AA may provide a surface on which an image of the display device DD is substantially displayed and on which a user's touch or command is input. The peripheral area PA may substantially correspond to a bezel area of the display device DD.

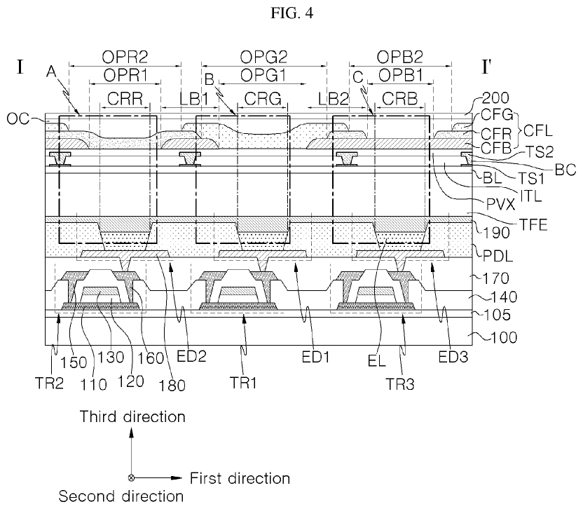

In some embodiments, an upper substrate 200 (see FIG. 4, etc.) may be provided as (or defined by) the window structure WS.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

The cover panel CP may be provided as a rear panel or rear housing of the display device DD. The cover panel CP may include a plate (e.g., a stainless steel (SUS) plate) that supports the display panel DP, a printed circuit board (PCB), and the like. The cover panel CP may also include an elastic body for absorbing shock of the display device DD.

In some embodiments, an active surface or a display surface of the display device DD or the display panel DP may be provided by an outer surface of the upper substrate 200 of FIG. 4 (e.g., an upper surface of the upper substrate 200).

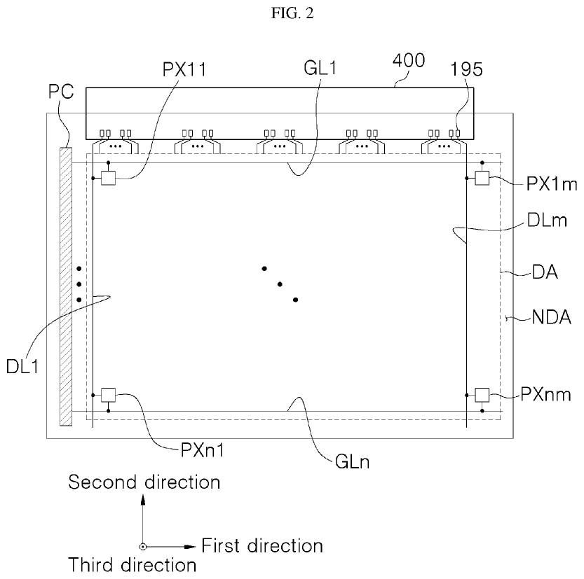

FIG. 2 is a schematic plan view illustrating a circuit structure of the display device according to embodiments.

Referring to FIG. 2, in an embodiment, a plurality of pixels PX11 to PXnm may be arranged in the display area DA of the display panel DP.

According to embodiments, gate lines GL1 to GLn that form first to n-th rows and data lines DL1 to DLm that form first to m-th columns may be disposed on a lower substrate 100 (see FIG. 4) of the display panel DP. Here, n and m are natural numbers greater than 1. Each of the pixels PX11 to PXnm may be connected to a gate line of a corresponding row among the plurality of gate lines GL1 to GLn and to a data line of a corresponding column among the plurality of data lines DL1 to DLm.

Each of the pixels PX11 to PXnm may include a pixel circuit including a transistor and a light-emitting device as described below. The pixel circuit may be connected to a gate line of a corresponding row among the plurality of gate lines GL1 to GLn and to a data line of a corresponding column among the plurality of data lines DL1 to DLm. Although not shown in detail in FIG. 2, the pixel circuit may be further connected to wiring such as a power line, a ground line, and the like.

FIG. 2 illustrates an embodiment where the data lines DL1 to DLm extend in the second direction and the gate lines GLI to GLn extend in the first direction, but it is not necessarily limited thereto.

A peripheral circuit PC may be disposed in the peripheral area PA of the display device DD or the non-display area NDA of the display panel DP. In an embodiment, for example, the peripheral circuit PC may include a gate driving circuit. The gate driving circuit may be integrated into the display panel DP through an oxide semiconductor gate (OSG) or an amorphous silicon gate (ASG) driving circuit process.

The display device DD may further include a printed circuit board 400. Pad portions 195 connected to the pixel circuit may be provided on one side portion of the non-display area NDA. The printed circuit board 400 may be electrically connected to the pixel circuit through the pad portions 195. In an embodiment, for example, the printed circuit board 400 may be electrically connected to the pad portions 195 through a heat-compression process using a conductive intermediate structure such as an anisotropic conductive film (ACF).

An integrated circuit (IC) such as a data driving circuit may be disposed on the printed circuit board 400. In some embodiments, the integrated circuit (IC) chip may be mounted on the printed circuit board 400 in the form of a chip-on-film (COF).

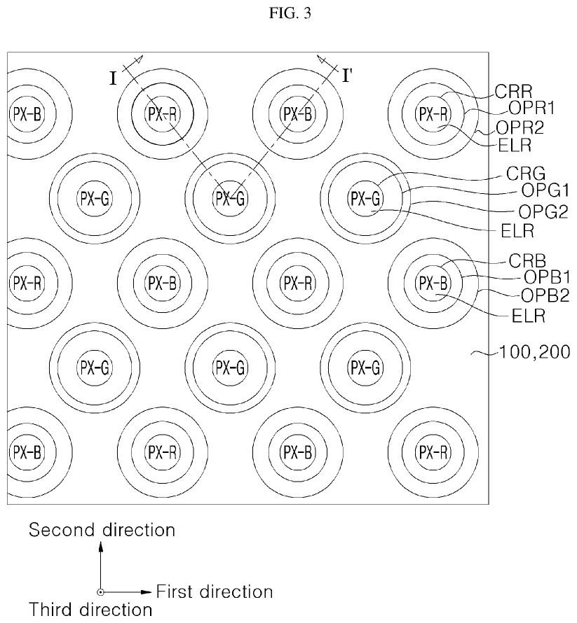

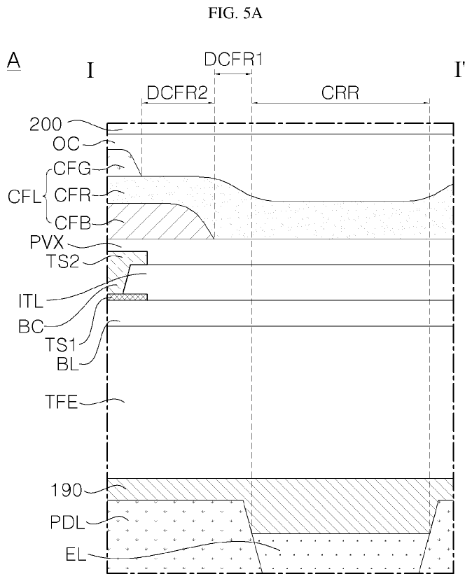

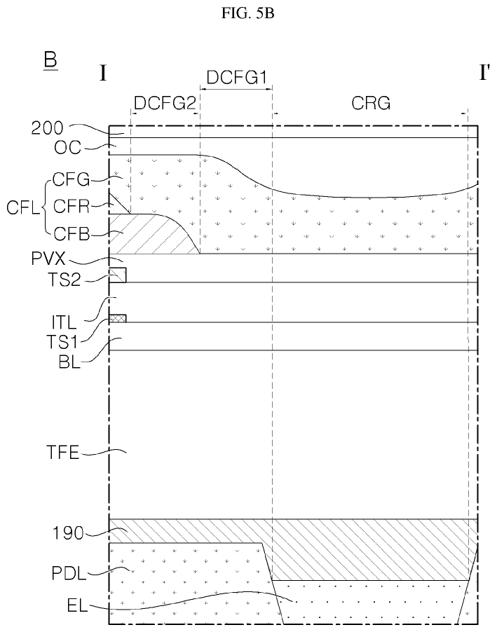

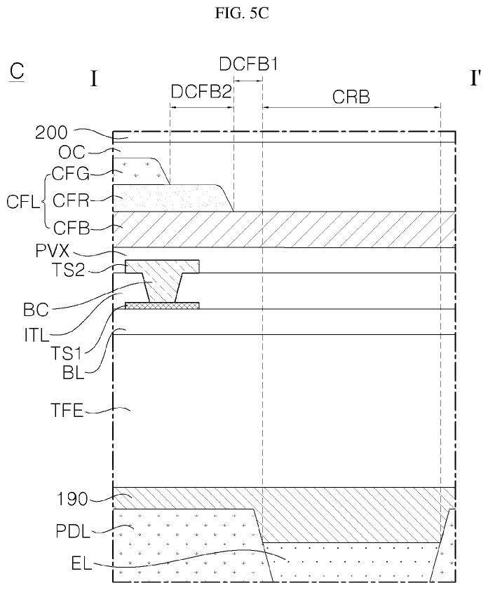

FIG. 3 is a plan view illustrating a pixel arrangement of the display device according to embodiments. FIG. 4 is a cross-sectional view taken along line I-I′ of FIG. 3 in the thickness direction (third direction) of the display device. FIGS. 5A, 5B and 5C are partially enlarged cross-sectional views of regions A, B and C of FIG. 4, respectively.

Referring to FIGS. 3 to 5C, in an embodiment, pixels of the display device DD may include a first pixel PX-G, a second pixel PX-R, and a third pixel PX-B. The first to third pixels PX-G, PX-R and PX-B may be pixels corresponding to different colors.

According to embodiments, the first pixel PX-G may be a region that emits green light. In an embodiment, for example, the first pixel PX-G may be a region that emits green light having a central wavelength in a range of about 500 nanometers (nm) to about 580 nm. The second pixel PX-R may be a region that emits red light. In an embodiment, for example, the second pixel PX-R may be a region that emits red light having a central wavelength in a range of about 600 nm to about 670 nm. The third pixel PX-B may be a region that emits blue light. In an embodiment, for example, the third pixel PX-B may be a region that emits blue light having a central wavelength in a range of about 420 nm to about 480 nm.

In an embodiment, as shown in FIG. 3, the second pixel PX-R and the third pixel PX-B may be alternately and repeatedly arranged in a same row (first direction). The first pixel PX-G may be repeatedly arranged in a different row from that of the second pixel PX-R and the third pixel PX-B.

In an embodiment, for example, the second pixel PX-R and the third pixel PX-B may be arranged in a same column (second direction), but the second pixel PX-R and the first pixel PX-G, and the third pixel PX-B and the first pixel PX-G may not be arranged in the same column.

In embodiments, the first pixel PX-G, the second pixel PX-R, and the third pixel PX-B may each have a circular shape or an elliptical shape in a plan view or when viewed in the third direction (or the thickness direction). Accordingly, diffraction caused by external light may be suppressed, thereby reducing reflectivity of external light and improving color reproducibility.

According to an embodiment, as shown in FIG. 4, the display device DD may include the lower substrate 100, transistors TR1, TR2 and TR3 arranged on the lower substrate 100, and light-emitting devices ED1, ED2 and ED3 connected to the transistors TR1, TR2 and TR3 respectively.

The lower substrate 100 may be provided as a base substrate or a back-plane substrate of the display device DD or the display panel DP. The lower substrate 100 may include a glass substrate, a ceramic substrate, or a plastic substrate. In some embodiments, the lower substrate 100 may include a polymer material having transparency and predetermined flexibility. In such embodiments, the lower substrate 100 may be employed in a transparent flexible, bendable, or foldable display device.

In an embodiment, the lower substrate 100 may include a polymer material such as polyimide, polysiloxane, epoxy resin, acrylic resin, polyester, polyarylate, polycarbonate, polyethersulfone, polyphenylene sulfide, or the like. In an embodiment, for example, the lower substrate 100 may include polyimide.

A buffer layer 105 may be disposed or formed on an upper surface of the lower substrate 100. Moisture penetrating through the lower substrate 100 may be blocked by the buffer layer 105, and impurity diffusion between the lower substrate 100 and a structure formed on the lower substrate 100 may also be blocked. The buffer layer 105 may be formed to extend across both a pixel region (or a light-emitting region) (such as regions indicated by PX-G, PX-R and PX-B in FIG. 3) and a non-pixel region of the lower substrate 100, and may entirely cover the upper surface of the lower substrate 100.

The buffer layer 105 may include an inorganic insulating material such as silicon oxide, silicon nitride, or silicon oxynitride. These may be used alone or in combination of two or more thereof. In some embodiments, the buffer layer 105 may have a laminated structure including a silicon oxide film and a silicon nitride film.

The buffer layer 105 may be formed by a deposition process such as a chemical vapor deposition (CVD) process, a sputtering process, an atomic layer deposition (ALD) process, etc., using the above-described inorganic insulating material.

The transistors TR1, TR2 and TR3 may be disposed on the buffer layer 105. In an embodiment, a first transistor TR1, a second transistor TR2, and a third transistor TR3 may be electrically connected to a first light-emitting device ED1, a second light-emitting device ED2, and a third light-emitting device ED3, respectively.

The transistors TR1, TR2 and TR3 may respectively include an active layer 110, a gate insulating layer 120, a gate electrode 130, and connection electrodes 150 and 160. The transistors TR1, TR2 and TR3 may be electrically connected to the light-emitting devices ED1, ED2 and ED3 of the first pixel PX-G, the second pixel PX-R, and the third pixel PX-B, respectively.

The active layer 110 may be disposed on the buffer layer 105 and may be patterned, for example, by a photolithography process so as to be repeatedly and regularly arranged in each pixel. In an embodiment, the active layer 110 may include a silicon compound such as polysilicon. Some regions of the active layer 110 may be doped with a p-type dopant or an n-type dopant, and the active layer 110 may include a source region, a drain region, and a channel region.

In an embodiment, the active layer 110 may include an oxide semiconductor such as indium gallium zinc oxide (IGZO), zinc tin oxide (ZTO), or indium tin zinc oxide (ITZO).

The gate insulating layer 120 may be formed on the active layer 110, and the gate electrode 130 may be laminated on the gate insulating layer 120. As shown in FIG. 4, the gate insulating layer 120 may be formed in a patterned shape that partially covers each active layer 110.

Alternatively, the gate insulating layer 120 may extend continuously across a plurality of pixels or light-emitting regions, and may be commonly applied to the first to third transistors TR1, TR2 and TR3.

The gate electrode 130 may overlap the channel region of the active layer 110 in the third direction.

The gate insulating layer 120 may be formed by the above-described deposition process using an inorganic insulating material such as silicon oxide, silicon nitride, silicon oxynitride, etc. In some embodiments, the gate insulating layer 120 may be formed in a patterned shape as shown in FIG. 4 by a photolithography process in which the gate electrode 130 is substantially used as an etching mask.

In some embodiments, the source region and the drain region may be formed or defined in the active layer 110 using the gate electrode 130 and the gate insulating layer 120 as masks.

An interlayer insulating layer 140 that covers the gate insulating layer 120 and the gate electrode 130 may be disposed or formed on the active layer 110. The connection electrodes 150 and 160, which contact or are electrically connected to the active layer 110, may be disposed or formed through the interlayer insulating layer 140.

The interlayer insulating layer 140 may be formed by the above-described deposition process using an inorganic insulating material such as silicon oxide, silicon nitride, silicon oxynitride, etc. The interlayer insulating layer 140 may be formed as a single-layer structure or a multi-layer structure including different materials.

In some embodiments, where the active layer 110 includes an oxide semiconductor, hydrogen (H) contained in the interlayer insulating layer 140 may diffuse or migrate into the active layer 110 through a heat treatment process during formation of the interlayer insulating layer 140. Accordingly, the carrier concentration may be increased by hydrogen, thereby forming the source region and the drain region with increased conductivity at side portions of the active layer 110.

The connection electrodes 150 and 160 may penetrate the interlayer insulating layer 140 and be connected to the active layer 110. In an embodiment where the gate insulating layer 120 is formed continuously and commonly across a plurality of light-emitting regions, the connection electrodes 150 and 160 may also penetrate the gate insulating layer 120.

The connection electrodes 150 and 160 may include a source electrode 150 connected to or in contact with the source region of the active layer 110, and a drain electrode 160 connected to or in contact with the drain region of the active layer 110.

The interlayer insulating layer 140 may be partially etched to form contact holes. In an embodiment, for example, contact holes that expose the source region and the drain region, respectively, may be defined or formed through the interlayer insulating layer 140. After a metal layer that sufficiently fills the contact holes is formed on the interlayer insulating layer 140, the metal layer may be partially etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, or Sc, an alloy thereof, or a nitride thereof. The gate electrode 130 and the connection electrodes 150 and 160 may be formed by the above-described deposition process.

A planarization layer 170 that covers the connection electrodes 150 and 160 may be disposed or formed on the interlayer insulating layer 140. The planarization layer 170 may accommodate a via structure that electrically connects the pixel electrode 180 and the drain electrode 160.

In some embodiments, the planarization layer 170 may include an organic material such as polyimide, epoxy resin, acrylic resin, polyester, siloxane resin, benzocyclobutene (BCB), etc. The planarization layer 170 may be formed by the above-described deposition process or a spin coating process.

A pixel electrode 180 may be provided or formed for each pixel on the lower substrate 100 to be electrically connected to the transistors TR1, TR2 or TR3. The pixel electrode 180 may be formed on the planarization layer 170 to be electrically connected to the drain electrode 160.

In an embodiment, for example, the planarization layer 170 may be partially etched to form a via hole that exposes an upper surface of the drain electrode 160. After a conductive layer including a metal material or a transparent conductive oxide is formed on an upper surface of the planarization layer 170 to sufficiently fill the via hole, the conductive layer may be etched to form the pixel electrode 180.

The pixel electrode 180 may be provided as an anode, and may include a high work function conductive material that promotes hole injection. The pixel electrode 180 may be provided as a transmissive electrode. The pixel electrode 180 may include a transparent conductive oxide such as indium tin oxide (ITO), indium zinc oxide (IZO), zinc oxide (ZnO), indium tin zinc oxide (ITZO), etc.

The pixel electrode 180 may also be provided as a semi-transmissive electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn, and Zn, a compound thereof (e.g., LiF) or an alloy of two or more thereof.

The pixel electrode 180 may have a single-layer structure or a multi-layer structure. In an embodiment, for example, the pixel electrode 180 may have a three-layer structure of ITO/Ag/ITO.

A pixel defining layer PDL that exposes an upper surface of the pixel electrode 180 may be disposed or formed on the planarization layer 170. A light-emitting region ELR including the first light-emitting device ED1, the second light-emitting device ED2, and the third light-emitting device ED3 may be defined by the side walls of the pixel defining layer PDL. A green light-emitting region, a red light-emitting region, and a blue light-emitting region are separated and defined by the pixel defining layer PDL, and the first light-emitting device ED1, the second light-emitting device ED2, and the third light-emitting device ED3 may correspond to a green light-emitting device, a red light-emitting device, and a blue light-emitting device, respectively.

The pixel defining layer PDL may be formed by applying a photosensitive organic material such as a polysiloxane resin, a polyimide resin, an acrylic resin, or the like, and then performing exposure and development processes. In some embodiments, the pixel defining layer PDL may also be formed by a printing process such as an inkjet printing process using a polymeric material or an inorganic material.

A light-emitting portion EL may be disposed in each light-emitting region ELR defined or formed by the pixel defining layer PDL. According to embodiments, the light-emitting portion EL may include a light-emitting layer containing an organic light-emitting material. In an embodiment, for example, the light-emitting portion EL may be formed by a process such as vacuum deposition, spin coating, inkjet printing, laser printing, casting, laser thermal transfer, or the like.

In some embodiments, the pixel defining layer PDL may be provided as a black pixel defining layer (black PDL, BPDL). Accordingly, light emitted from the light-emitting devices ED1, ED2 and ED3 may be extracted to the outside through only a color filter layer CFL without a separate polarization layer (e.g., an on-cell film structure).

In some embodiments, the pixel defining layer PDL may expose the light-emitting portion EL through an opening. The term “exposure” may refer to exposure of the upper surface. In an embodiment, for example, the light emitted from the exposed light-emitting portion EL may be emitted to the outside through the color filter layer CFL.

In some embodiments, the opening may have a circular shape or an elliptical shape in a plan view. Accordingly, diffraction and/or reflection caused by external light may be further suppressed.

A counter electrode 190 may be disposed on a side surface and an upper surface of the pixel defining layer PDL and on the light-emitting portions EL. The counter electrode 190 may be a common electrode that is provided continuously and commonly to a plurality of light-emitting regions or pixels.

The counter electrode 190 may be provided as an electron injection electrode or a cathode. The counter electrode 190 may include a metal, an alloy, an electrically conductive compound, or the like having a low work function.

In an embodiment, for example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in combination of two or more thereof.

The counter electrode 190 may be provided as a transmissive electrode, a semi-transmissive electrode, or a reflective electrode. The counter electrode 190 may have a single-layer structure or a multi-layer structure.

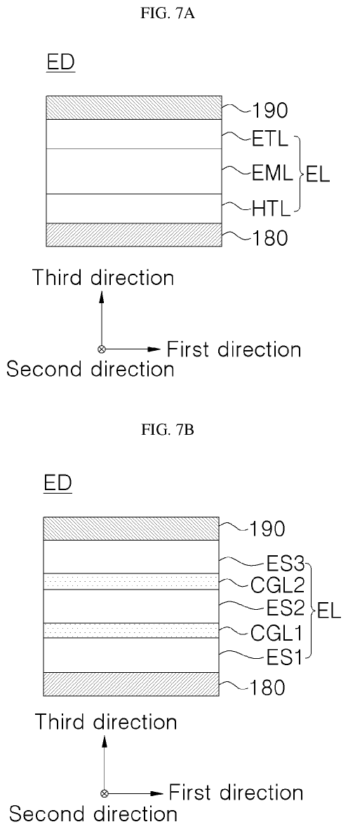

The light-emitting devices ED1, ED2 and ED3 may be defined by the pixel electrode 180, the light-emitting portion EL, and the counter electrode 190 described above. The light-emitting devices ED1, ED2 and ED3 may be provided as organic light-emitting diode (OLED) elements. The configuration and structure of the light-emitting portion EL and the light-emitting devices ED1, ED2 and ED3 will be described in greater detail with reference to FIGS. 7A and 7B below.

An encapsulation layer TFE may be disposed or formed on the counter electrode 190. The encapsulation layer TFE may be disposed on the pixel defining layer PDL and the light-emitting devices ED1, ED2 and ED3 to protect the light-emitting devices ED1, ED2 and ED3 from moisture or oxygen, and to allow light generated from the light-emitting portion EL to be efficiently emitted toward the outside.

The encapsulation layer TFE may include at least one selected from: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy resin (e.g., aliphatic glycidyl ether (AGE)), or a combination thereof; and a combination of an inorganic film and an organic film.

The encapsulation layer TFE may be formed in a single-layer or multi-layer structure. In some embodiments, the encapsulation layer TFE may have a sequentially laminated structure including a first inorganic film, an organic film, and a second inorganic film.

A touch sensor structure may be disposed or formed on the encapsulation layer TFE.

The touch sensor structure may include a first touch sensor electrode layer TS1 and a second touch sensor electrode layer TS2. The touch sensor layer may further include a bridge contact BC that electrically connects the first touch sensor electrode layer TS1 and the second touch sensor electrode layer TS2. The first touch sensor electrode layer TS1 and the second touch sensor electrode layer TS2 may be disposed in different layers or at different levels with an intermediate insulating layer ITL interposed therebetween.

In some embodiments, the first touch sensor electrode layer TS1 and the second touch sensor electrode layer TS2 may be disposed under the light-shielding portions LB1 and LB2. In an embodiment, for example, the first and second touch sensor electrode layers TS1 and TS2 may be disposed at positions overlapping the light-shielding portions LB1 and LB2.

In some embodiments, the barrier layer BL may be disposed or formed on the encapsulation layer TFE, and the first touch sensor electrode layer TS1 may be disposed or formed on the barrier layer BL. The intermediate insulating layer ITL may cover the first touch sensor electrode layer TS1.

The barrier layer BL and the intermediate insulating layer ITL may be formed by a deposition process such as a CVD process using an inorganic insulating material such as silicon oxide, silicon nitride, silicon oxynitride, etc. The barrier layer BL and the intermediate insulating layer ITL may also be formed by a coating process such as a spin coating process using an organic insulating material such as a siloxane-based resin, an acrylic-based resin, an epoxy-based resin, etc.

The second touch sensor electrode layer TS2 may be formed on the intermediate insulating layer ITL. The bridge contact BC may penetrate the intermediate insulating layer ITL to electrically connect some of sensing electrodes of the second touch sensor electrode layer TS2 and the first touch sensor electrode layer TS1 with each other. The bridge contact BC may be formed as a substantially unitary member with the second touch sensor electrode layer TS2, that is, the bridge contact BC may be integrally formed with the second touch sensor electrode layer TS2 as a single unitary indivisible part.

The first touch sensor electrode layer TS1 and the second touch sensor electrode layer TS2 may be formed using the above-described metal and/or alloy or the above-described transparent conductive oxide. In an embodiment, for example, the first touch sensor electrode layer TS1 and the second touch sensor electrode layer TS2 may be formed by a sputtering process, a deposition process, or a photolithography process.

In some embodiments, the first touch sensor electrode layer TS1 and the second touch sensor electrode layer TS2 may have a laminated structure of a plurality of metal layers, such as a laminated structure including a Ti layer, an Al layer and another Ti layer. Accordingly, capacitance for touch sensing may be easily formed by reducing resistance while suppressing oxidation-induced degradation to the first touch sensor electrode layer TS1 and the second touch sensor electrode layer TS2.

A passivation layer PVX may be formed on the second touch sensor electrode layer TS2. Alternatively, the passivation layer PVX that covers the second touch sensor electrode layer TS2 may be formed on the intermediate insulating layer ITL. The passivation layer PVX may include an organic insulating material or the above-described inorganic insulating material.

In some embodiments, a polarizing plate may be disposed on the passivation layer PVX. In an embodiment, for example, the polarizing plate may include a polarizer including a polyvinyl alcohol (PVA)-based resin oriented in a specific direction, and a protective film formed on an upper surface and/or a lower surface of the polarizer and including a cellulose-based resin such as triacetyl cellulose (TAC).

The polarizing plate may reduce or suppress external light reflection generated from lower structures of the display device DD.

In some embodiments, referring to FIG. 4, the color filter layer CFL may be disposed on the passivation layer PVX. In an embodiment, the display device DD may have an on-cell film (OCF) structure in which the polarizing plate is omitted. In an embodiment, for example, a polarizing plate may not be formed on the front surface of the display panel DP. In such an embodiment, the pixel defining layer PDL may include or be formed of a black organic material, and light-shielding portions LB1 and LB2 and the color filter layer CFL may be provided on an upper portion of the pixel defining layer PDL, so that even if external light is incident inside, the external light may be prevented from being reflected by the anode or the like and transmitted to the user. In such an embodiment, since the polarizing plate is not formed, light emitted from the light-emitting layer EML (see FIG. 7A) is not partially absorbed by the polarizing plate, and the luminance is not reduced, thereby providing a display device DD having a maximum luminance value of 2000 candelas per square meter(cd/m²) or greater.

In embodiments, the color filter layer CFL may include a first color filter CFG, a second color filter CFR, and a third color filter CFB.

In an embodiment, for example, the color filters CFG, CFR and CFB may selectively transmit only light in a specific wavelength band and substantially absorb the remaining light. Accordingly, the color purity of the display device DD may be increased, as well as reflection of external light may be reduced.

The first color filter CFG may overlap the first light-emitting device ED1 in the thickness direction (the third direction), the second color filter CFR may overlap the second light-emitting device ED2 in the thickness direction, and the third color filter CFB may overlap the third light-emitting device ED3 in the thickness direction. Accordingly, the first color filter CFG, the second color filter CFR, and the third color filter CFB may correspond to the first pixel PX-G, the second pixel PX-R, and the third pixel PX-B, respectively.

In an embodiment, for example, the first color filter CFG, the second color filter CFR, and the third color filter CFB may be provided as a green color filter, a red color filter, and a blue color filter, respectively.

The first color filter CFG may transmit green light having a central wavelength in a range of about 500 nm to about 580 nm, for example. The second color filter CFR may transmit red light having a central wavelength in a range of about 600 nm to about 670 nm, for example. The third color filter CFB may transmit blue light having a central wavelength in a range of about 420 nm to about 480 nm, for example.

The color filters CFG, CFR and CFB may each include a polymeric photosensitive resin, and a colorant including a pigment and/or a dye. The first color filter CFG may include a green pigment and/or a green dye, the second color filter CFR may include a red pigment and/or a red dye, and the third color filter CFB may include a blue pigment and/or a blue dye.

According to embodiments, the color filter layer CFL may include the light-shielding portions LB1 and LB2 and color forming portions CRG, CRR and CRB.

The light-shielding portions LB1 and LB2 may be positioned above the pixel defining layer PDL, and may be disposed at positions overlapping the pixel defining layer PDL, for example.

The light-shielding portions LB1 and LB2 may be defined as regions where two or more of the first color filter CFG, the second color filter CFR, and the third color filter CFB overlap each other in the thickness direction (the third direction). In a portion where all three of the first color filter CFG, the second color filter CFR, and the third color filter CFB overlap each other, light emitted from the light-emitting portion EL may be effectively blocked.

In an embodiment, the light-shielding portions LB1 and LB2 may not include a black matrix. Conventionally, a black matrix was used to partition color filters and block light, but if two or more of the first color filter CFG, the second color filter CFR, and the third color filter CFB are provided to overlap each other to effectively block light, the black matrix may be omitted.

In an embodiment, when another color filter is provided to overlap on a color filter, the end of the lower color filter and the end of the upper color filter may overlap each other with a spacing therebetween in a plan view.

Referring to FIGS. 3 to 5C, the light-emitting region ELR may be defined by a boundary between the pixel defining layer PDL and the light-emitting portion EL, and may correspond to the color forming portions CRG, CRR and CRB of the color filter layer CFL. The light-shielding portions LB1 and LB2 may sequentially overlap one of the color filter CFG, CFR and CFB extending from the color forming portions CRG, CRR and CRB, along with the other two color filters, and the ends of the overlapping color filters may not be aligned at the same position in the thickness direction (third direction) but may instead disposed to overlap each other with a spacing therebetween in a plan view. In an embodiment, for example, in the case of the first pixel PX-G, the region defined by the boundary of the lowermost third color filter CFB may form a first opening (e.g., a first-3rd opening OPG1). The second color filter CFR overlapped thereon may be disposed such that its end is spaced apart from the end of the lower third color filter CFB by a separation distance DCFG2, and the region defined by the boundary of the second color filter CFR may form a second opening (e.g., a first-2nd opening OPG2). Accordingly, light efficiency and color reproducibility may be further improved, reflectivity of external light may be reduced, and diffraction caused by external light may also be reduced.

The color forming portions CRG, CRR and CRB are located above the light-emitting portion EL and may be defined or partitioned, for example, as regions overlapping the light-emitting region ELR.

In an embodiment, the color forming portions CRG, CRR and CRB do not include a plurality of overlapping color filters, for example, the first color forming portion CRG, the second color forming portion CRR, and the third color forming portion CRB may respectively include the first color filter CFG, the second color filter CFR, and the third color filter CFB, and may transmit lights of different colors. In an embodiment, for example, the first color forming portion CRG, the second color forming portion CRR, and the third color forming portion CRB may transmit green, red, and blue lights, respectively.

In embodiments, a shorter separation distance DCFG1 between a point corresponding to an end of the pixel defining layer PDL in the first color forming portion CRG and either the second color filter CFR or the third color filter CFB of the adjacent light-shielding portions LB1 and LB2 may be different from a shorter separation distance DCFR1 between a point corresponding to an end of the pixel defining layer PDL in the second color forming portion CRR and either the first color filter CFG or the third color filter CFB of the adjacent light-shielding portion LB1. Since the side-view color characteristics may vary depending on the type of light emitted from the light-emitting portion EL, the side-view color characteristics may be improved by differentiating the shorter separation distances DCFG1 and DCFR1.

In embodiments, the shorter separation distance DCFGI between the point corresponding to the end of the pixel defining layer PDL in the first color forming portion CRG and either the second color filter CFR or the third color filter CFB of the adjacent light-shielding portions LB1 and LB2 may be different from a shorter separation distance DCFB1 between a point corresponding to an end of the pixel defining layer PDL in the third color forming portion CRB and either the first color filter CFG or the second color filter CFR of the adjacent light-shielding portion LB2.

As described above, the side-view color characteristics may be improved by differentiating the shorter separation distances DCFG1 and DCFB1.

In an embodiment, the shorter separation distance DCFG1 in the first color forming portion CRG may be greater than the shorter separation distance DCFR1 in the second color forming portion CRR and/or the shorter separation distance DCFB1 in the third color forming portion CRB.

In an embodiment, for example, light emitted from the light-emitting portion EL may be constructively interfered (i.e., strongly resonant) light. In an embodiment, for example, when constructively interfered light is emitted from the light-emitting portion EL corresponding to the first color forming portion CRG and passes through the first color forming portion CRG, the shorter separation distance DCFG1 in the first color forming portion CRG may be greater than the shorter separation distance DCFR1 in the second color forming portion CRR and/or the shorter separation distance DCFB1 in the third color forming portion CRB, thereby improving the side-view color characteristics.

In an embodiment, for example, the shorter separation distance DCFG1 in the first color forming portion CRG may be at least about 1 micrometer (μm) greater than the shorter separation distance DCFR1 in the second color forming portion CRR and/or the shorter separation distance DCFB1 in the third color forming portion CRB. In such an embodiment, the side-view color characteristics may be effectively improved.

In an embodiment, the shorter separation distance DCFR1 between the point corresponding to the end of the pixel defining layer PDL in the second color forming portion CRR and either the first color filter CFG or the third color filter CFB of the adjacent light-shielding portion LB1 may be different from the shorter separation distance DCFB1 between the point corresponding to the end of the pixel defining layer PDL in the third color forming portion CRB and either the first color filter CFG or the second color filter CFR of the adjacent light-shielding portion LB2. In an embodiment, for example, the shorter separation distance DCFR1 may be greater than the shorter separation distance DCFB1. Accordingly, the side-view color characteristics may be improved.

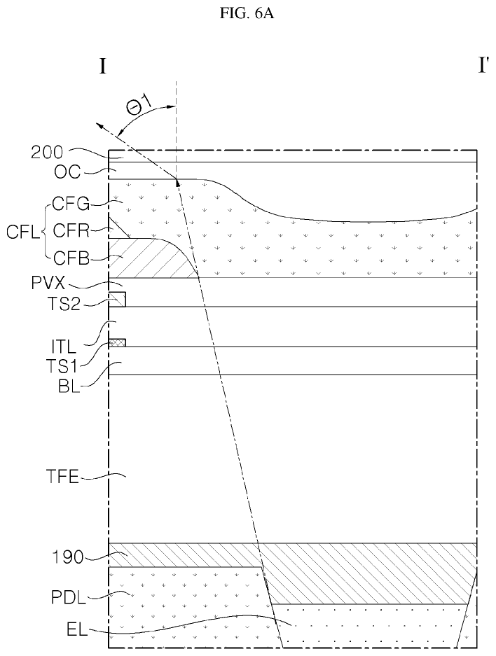

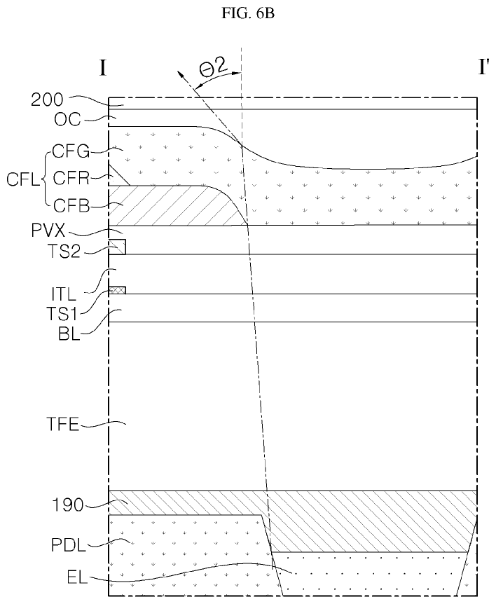

FIGS. 6A and 6B are schematic cross-sectional views illustrating light emission angles in region B of FIG. 4 for display devices of an embodiment and the prior art (a comparative example), respectively.

FIG. 6B shows a case of the prior art (or the comparative example) in which the shorter separation distance DCFG1 in the first color forming portion CRG is equal to the shorter separation distances DCFR1 and DCFB1 in the other color forming portions CRR and CRB, whereas FIG. 6A shows a case according to an embodiment in which the shorter separation distance DCFG1 in the first color forming portion CRG is greater than the shorter separation distances DCFR1 and DCFB1 in the other color forming portions CRR and CRB. In an embodiment, by increasing the shorter separation distance DCFG1, an angle at which light is emitted laterally (i.e., an angle inclined toward a planar direction formed by the first and second directions with respect to the third direction) may be increased (i.e., θ1>θ2), and thus, the side-view color characteristics of the light may be enhanced.

In embodiments, a longer separation distance (DCFG1+DCFG2) between the point corresponding the an end of the pixel defining layer PDL in the first color forming portion CRG and either the second color filter CFR or the third color filter CFB of the adjacent light-shielding portions LB1 and LB2 may be different from a longer separation distance (DCFR1+DCFR2) between the point corresponding to the end of the pixel defining layer PDL in the second color forming portion CRR and either the first color filter CFG or the third color filter CFB of the adjacent light-shielding portion LB1. The side-view color characteristics may vary depending on the type of light emitted from the light-emitting portion EL, and by differentiating the separation distances DCFG1, DCFR1, DCFG2 and/or DCFR2, light efficiency and color reproducibility may be further improved, reflectivity of external light and diffraction caused by external light may be reduced, and the side-view color characteristics may be improved.

In embodiments, the longer separation distance (DCFG1+DCFG2) between the point corresponding to the end of the pixel defining layer PDL in the first color forming portion CRG and either the second color filter CFR or the third color filter CFB of the adjacent light-shielding portions LB1 and LB2 may be different from a longer separation distance (DCFB1+DCFB2) between the point corresponding to the end of the pixel defining layer PDL in the third color forming portion CRB and either the first color filter CFG or the second color filter CFR of the adjacent light-shielding portion LB2. As described above, by differentiating the separation distances DCFG1, DCFB1, DCFG2 and/or DCFB2, light efficiency and color reproducibility may be further improved, reflectivity of external light and diffraction caused by external light may be reduced, and side-view color characteristics may be improved.

In an embodiment, the longer separation distance (DCFG1+DCFG2) in the first color forming portion CRG may be greater than the longer separation distance (DCFR1+DCFR2) in the second color forming portion CRR and/or the longer separation distance (DCFB1+DCFB2) in the third color forming portion CRB. Accordingly, the light efficiency and color reproducibility may be further improved, reflectivity of external light and diffraction caused by external light may be reduced, and the side-view color characteristics may be improved.

Since the shorter separation distances DCFG1 and DCFR1 in the first color forming portion CRG and the second color forming portion CRR are different from each other, in embodiments, the smaller one (e.g., an opening OPG1 or the opening OPG2) of a first-2nd opening OPG2 defined by the second color filter CFR and a first-3rd opening OPG1 defined by the third color filter CFB in the first pixel PX-G corresponding to the first color forming portion CRG may have an area different from that of the smaller one (e.g., an opening OPRI or the opening OPR2) of a second-1st opening OPR2 defined by the first color filter CFG and a second-3rd opening OPRI defined by the third color filter CFB in the second pixel PX-R corresponding to the second color forming portion CRR. Accordingly, the side-view color characteristics may be improved.

In embodiments, the smaller one (e.g., the opening OPG1 or the opening OPG2) of the first-2nd opening OPG2 defined by the second color filter CFR and the first-3rd opening OPG1 defined by the third color filter CFB in the first pixel PX-G corresponding to the first color forming portion CRG may have an area different from that of the smaller one (e.g., an opening OPB1 or the opening OPB2) of a third-1st opening OPB2 defined by the first color filter CFG and a third-2nd opening OPB1 defined by the second color filter CFR in the third pixel PX-B corresponding to the third color forming portion CRB. As described above, the side-view color characteristics may be improved by differentiating the areas.

In an embodiment, the smaller one of the first-2nd opening OPG2 and the first-3rd opening OPG1 of the first pixel PX-G may have an area larger than that of the smaller one of the second-1st opening OPR2 and the second-3rd opening OPR1 of the second pixel PX-R, or may have an area larger than that of the smaller one of the third-1st opening OPB2 and the third-2nd opening OPB1 of the third pixel PX-B. In an embodiment, for example, when light emitted from the first pixel PX-G is constructively interfered (strongly resonant) light, the side-view color characteristics may be improved by making the area larger than that of other pixels.

In an embodiment, the smaller one of the second-1st opening OPR2 and the second-3rd opening OPR1 of the second pixel PX-R may have an area different from that of the smaller one of the third-1st opening OPB2 and the third-2nd opening OPB1 of the third pixel PX-B. In an embodiment, for example, the smaller one of the second-1st opening OPR2 and the second-3rd opening OPR1 of the second pixel PX-R may have an area larger than that of the smaller one of the third-1st opening OPB2 and the third-2nd opening OPB1 of the third pixel PX-B. Accordingly, the side-view color characteristics may be improved.

In embodiments, the larger one (e.g., the opening OPG1 or the opening OPG2) of the first-2nd opening OPG2 defined by the second color filter CFR and the first-3rd opening OPG1 defined by the third color filter CFB in the first pixel PX-G corresponding to the first color forming portion CRG may have an area different from that of the larger one (e.g., the opening OPR1 or the opening OPR2) of the second-1st opening OPR2 defined by the first color filter CFG and the second-3rd opening OPR1 defined by the third color filter CFB in the second pixel PX-R corresponding to the second color forming portion CRR. The side-view color characteristics may vary depending on the type of light emitted from the light-emitting portion EL, and by differentiating the areas, light efficiency and color reproducibility may be further improved, reflectivity of external light and diffraction caused by external light may be reduced, and the side-view color characteristics may be improved.

In embodiments, the larger one (e.g., the opening OPG1 or the opening OPG2) of the first-2nd opening OPG2 defined by the second color filter CFR and the first-3rd opening OPG1 defined by the third color filter CFB in the first pixel PX-G corresponding to the first color forming portion CRG may have an area different from that of the larger one (e.g., the opening OPB1 or the opening OPB2) of the third-1st opening OPB2 defined by the first color filter CFG and the third-2nd opening OPB1 defined by the second color filter CFR in the third pixel PX-B corresponding to the third color forming portion CRB. As described above, by differentiating the separation distances DCFG2 and DCFB2, light efficiency and color reproducibility may be further improved, reflectivity of external light and diffraction caused by external light may be reduced, and side-view color characteristics may be improved.

In an embodiment, the larger one of the first-2nd opening OPG2 and the first-3rd opening OPG1 of the first pixel PX-G may have an area larger than that of the larger one of the second-1st opening OPR2 and the second-3rd opening OPR1 of the second pixel PX-R, and/or may have an area larger than that of the larger one of the third-1st opening OPB2 and the third-2nd opening OPB1 of the third pixel PX-B. Accordingly, light efficiency and color reproducibility may be further improved, reflectivity of external light and diffraction caused by external light may be reduced, and side-view color characteristics may be improved.

In embodiments, an overcoat layer OC may be disposed on the color filter layer CFL.

In an embodiment, for example, the overcoat layer OC may be provided as a planarization layer that covers an upper surface of the color filter layer CFL. Accordingly, the upper substrate 200 may be laminated on the overcoat layer OC so as to be stably disposed on the color filter layer CFL.

FIGS. 7A and 7B are schematic cross-sectional views illustrating the light-emitting devices according to embodiments.

Referring to FIGS. 7A and 7B, the light-emitting device ED may include the light-emitting portion EL disposed between the pixel electrode 180 and the counter electrode 190.

In an embodiment, as shown in FIG. 7A, the light-emitting portion EL may include a hole transport layer HTL, a light-emitting layer EML, and an electron transport layer ETL. According to embodiments, the light-emitting portion EL including the hole transport layer HTL, the light-emitting layer EML, and the electron transport layer ETL, and the counter electrode 190 may be sequentially laminated on the upper surface of the pixel electrode 180.

In some embodiments, a hole injection layer may be further disposed between the pixel electrode 180 and the hole transport layer HTL. An electron injection layer may be further disposed between the counter electrode 190 and the electron transport layer ETL.

In some embodiments, the light-emitting portion EL may include the light-emitting layer EML containing an organic light-emitting material capable of emitting blue light having a central wavelength in a range of about 420 nm to about 480 nm, for example.

As shown in FIG. 7B, the light-emitting portion EL may include a plurality of light-emitting structures ES1, ES2 and ES3. Each of the light-emitting structures ES1, ES2 and ES3 may include a hole transport layer, a light-emitting layer, and an electron transport layer. According to embodiments, the light-emitting device ED of FIG. 7B may be a light-emitting device having a tandem structure.

Charge generation layers CGL1 and CGL2 may be disposed between the adjacent light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 disposed between a first light-emitting structure ES1 and a second light-emitting structure ES2, and a second charge generation layer CGL2 disposed between the second light-emitting structure ES2 and a third light-emitting structure ES3.

According to embodiments, the first light-emitting structure ES1, the first charge generation layer CGL1, the second light-emitting structure ES2, the second charge generation layer CGL2, the third light-emitting structure ES3, and the counter electrode 190 may be sequentially laminated on the upper surface of the pixel electrode 180.

In some embodiments, as shown in FIG. 4, the light-emitting portions EL may be patterned within a limited light-emitting region defined by the pixel defining layer PDL. Accordingly, the light-emitting portions EL may be separated from each other in the form of spaced islands in each of the plurality of pixels.

In some embodiments, the light-emitting portion EL may extend continuously and commonly across the upper surfaces of the plurality of pixels and the pixel defining layer PDL.

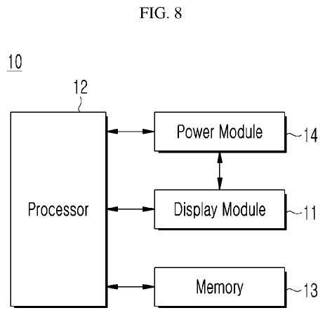

FIG. 8 is a block diagram of an electronic device according to an embodiment.

Referring to FIG. 8, an electronic device 10 according to an embodiment may include a display module 11, a processor 12, a memory 13 and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for an operation of the processor 12 or the display module 11. When the processor 12 executes an application stored in the memory 13, an image data signal and/or an input control signal may be transmitted to the display module 11, and then, the display module 11 may process the received signal and output image information through the display screen.

The power module 14 may include a power supply module such as a power adapter or a battery device, and a power conversion module that converts power supplied by the power supply module to generate power used for an operation of the electronic device 10.

At least one of the above-described components of the electronic device 10 may be included in the display device according to the embodiments described above. In addition, some parts of individual modules functionally integrated in a single module may be included in the display device, while other parts may be provided separately from the display device. In an embodiment, for example, the display device may include the display module 11, whereas the processor 12, memory 13 and power module 14 may be provided as parts of another device within the electronic device 10 rather than the display device.

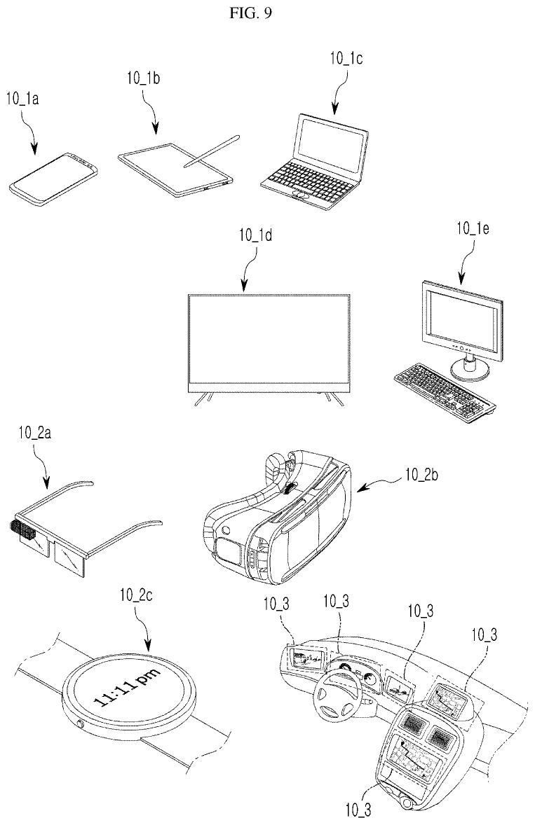

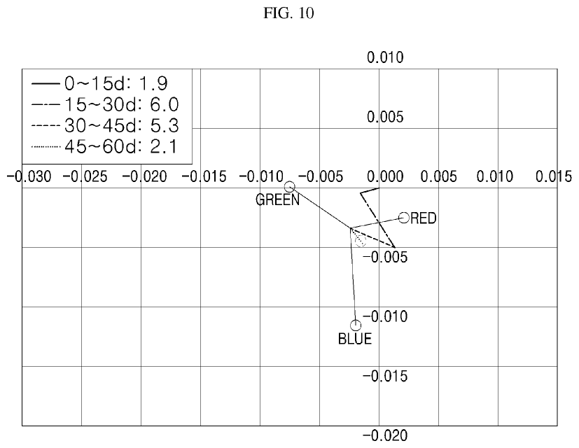

FIG. 9 is a set of schematic views illustrating electronic devices according to various embodiments.

Referring to FIG. 9, various electronic devices to which the display device according to the embodiments is applied may include not only image display electronic devices such as a smartphone 10 _1a, a tablet personal computer (PC) 10_1b, a laptop computer 10_1c, a television (TV) 10_1d, a desktop monitor 10_1e, etc., but also wearable electronic devices including a display module such as smart glasses 10_2a, a head-mounted display 10_2b, a smart watch 10_2c, etc., and vehicle electronic devices 10_3 including display modules such as a center information display (CID) arranged on an instrument panel, center fascia, or dashboard of a vehicle, and a room mirror display.

Hereinafter, experimental examples are presented to help understand the present disclosure; however, the following experimental examples are only illustrative of the present disclosure and are not intended to limit the scope of the claims. It will be apparent to those skilled in the art that various changes and modifications to the examples are possible within the scope and technical spirit of the present disclosure, and it is also natural that such changes and modifications fall within the scope of the claims.

### Experimental Example

The display device shown in FIGS. 4 to 5C was manufactured, and the first light-emitting device ED1, the second light-emitting device ED2, and the third light-emitting device ED3 were configured to emit green, red, and blue lights, respectively. Accordingly, the first color filter CFG, the second color filter CFR, and the third color filter CFB were set as a green color filter, a red color filter, and a blue color filter, respectively.

In the example, the shorter separation distance DCFGI in the green pixel was set to be about 1.2 μm longer than the shorter separation distances DCFR1 and DCFB1 of other pixels. In contrast, the comparative example was manufactured in the same manner as the example, except that the shorter separation distances DCFG1, DCFR1 and DCFB1 in each pixel were all equal to each other.

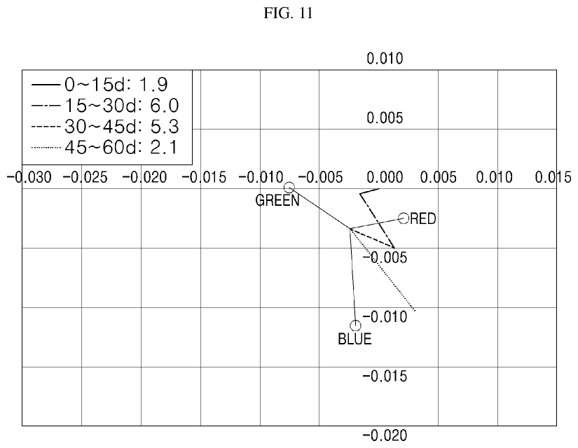

For the display devices of the example and comparative example, the perceived color was measured at increasing side viewing angles from the vertical upward direction (third direction) based on 0 degrees (°). The measured color was plotted on a color coordinate, and the results are shown in FIG. 10 (example) and FIG. 11 (comparative example).

Referring to FIGS. 10 and 11, it can be confirmed that the comparative example, where the separation distances are the same, exhibits a significant reddish tint at high viewing angles of about 45 degrees or greater. However, in the example, where the shorter separation distance DCFG1 of the green pixel is different from the shorter separation distances DCFR1 and DCFB1 of the other pixels, no reddish tint appears even at high viewing angles, indicating that the side-view color characteristics are improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a lower substrate;
pixel electrodes disposed on the lower substrate;
a pixel defining layer which defines pixels overlapping the pixel electrodes on the lower substrate;
light-emitting portions disposed on the pixel electrodes;
light-shielding portions disposed above the pixel defining layer; and
a color filter layer comprising a first color forming portion, a second color forming portion, and a third color forming portion, which are positioned above the light-emitting portions, wherein the first color forming portion, the second color forming portion, and the third color forming portion transmit lights of different colors,
wherein the first color forming portion, the second color forming portion and the third color forming portion comprise a first color filter, a second color filter and a third color filter, respectively,
wherein in the light-shielding portion, the first color filter, the second color filter, and the third color filter overlap one another in a thickness direction, and
a shorter separation distance between a point corresponding to an end of the pixel defining layer in the first color forming portion and either the second color filter or the third color filter of an adjacent light-shielding portion of the first color forming portion is different from a shorter separation distance between a point corresponding to an end of the pixel defining layer in the second color forming portion and either the first color filter or the third color filter of an adjacent light-shielding portion of the second color forming portion.

2. The display device according to claim 1, wherein a longer separation distance between the point corresponding to the end of the pixel defining layer in the first color forming portion and either the second color filter or the third color filter of the adjacent light-shielding portion of the first color forming portion is different from a longer separation distance between the point corresponding to the end of the pixel defining layer in the second color forming portion and either the first color filter or the third color filter of the adjacent light-shielding portion of the second color forming portion.

3. The display device according to claim 1, wherein the shorter separation distance between the point corresponding to the end of the pixel defining layer in the first color forming portion and either the second color filter or the third color filter of the adjacent light-shielding portion of in the first color forming portion is different from a shorter separation distance between a point corresponding to an end of the pixel defining layer in the third color forming portion and either the first color filter or the second color filter of an adjacent light-shielding portion of the third color forming portion.

4. The display device according to claim 1, wherein a longer separation distance between the point corresponding to the end of the pixel defining layer in the first color forming portion and either the second color filter or the third color filter of the adjacent light-shielding portion of the first color forming portion is different from a longer separation distance between a point corresponding to an end of the pixel defining layer in the third color forming portion and either the first color filter or the second color filter of an adjacent light-shielding portion of the third color forming portion.

5. The display device according to claim 1, wherein the shorter separation distance between the point corresponding to the end of the pixel defining layer in the first color forming portion and either the second color filter or the third color filter of the adjacent light-shielding portion of the first color forming portion is greater than the shorter separation distance between the point corresponding to the end of the pixel defining layer in the second color forming portion and either the first color filter or the third color filter of the adjacent light-shielding portion of the second color forming portion.

6. The display device according to claim 1, wherein the shorter separation distance between the point corresponding to the end of the pixel defining layer in the first color forming portion and either the second color filter or the third color filter of the adjacent light-shielding portion of the first color forming portion is greater than a shorter separation distance between a point corresponding to an end of the pixel defining layer in the third color forming portion and either the first color filter or the second color filter of an adjacent light-shielding portion of the third color forming portion.

7. The display device according to claim 1, wherein the smaller one of openings defined by the second color filter or the third color filter in a pixel corresponding to the first color forming portion has an area different from an area of the smaller one of openings defined by the first color filter or the third color filter in a pixel corresponding to the second color forming portion.

8. The display device according to claim 1, wherein the larger one of openings defined by the second color filter or the third color filter in a pixel corresponding to the first color forming portion has an area different from an area of the larger one of openings defined by the first color filter or the third color filter in a pixel corresponding to the second color forming portion.

9. The display device according to claim 1, wherein the smaller one of openings defined by the second color filter or the third color filter in a pixel corresponding to the first color forming portion has an area different from an area of the smaller one of openings defined by the first color filter or the second color filter in a pixel corresponding to the third color forming portion.

10. The display device according to claim 1, wherein the larger one of openings defined by the second color filter or the third color filter in a pixel corresponding to the first color forming portion has an area different from an area of the larger one of openings defined by the first color filter or the second color filter in a pixel corresponding to the third color forming portion.

11. The display device according to claim 1, wherein the smaller one of openings defined by the second color filter or the third color filter in a pixel corresponding to the first color forming portion has an area larger than an area of the smaller one of openings defined by the first color filter or the third color filter in a pixel corresponding to the second color forming portion.

12. The display device according to claim 1, wherein the smaller one of openings defined by the second color filter or the third color filter in a pixel corresponding to the first color forming portion has an area larger than an area of the smaller one of openings defined by the first color filter or the second color filter in a pixel corresponding to the third color forming portion.

13. The display device according to claim 1, wherein the shorter separation distance between the point corresponding to the end of the pixel defining layer in the first color forming portion and either the second color filter or the third color filter of the adjacent light-shielding portion of the first color forming portion is at least 1 um greater than the shorter separation distance between the point corresponding to the end of the pixel defining layer in the second color forming portion and either the first color filter or the third color filter of the adjacent light-shielding portion of the second color forming portion.

14. The display device according to claim 1, wherein the light-shielding portion does not include a black matrix.

15. The display device according to claim 1, wherein the first color forming portion transmits green light,
the second color forming portion transmits red light, and
the third color forming portion transmits blue light.

16. The display device according to claim 1, wherein light transmitted from the first color forming portion is constructively interfered light.

17. A display device comprising:
a lower substrate;
pixel electrodes disposed on the lower substrate;
a pixel defining layer which defines pixels overlapping the pixel electrodes on the lower substrate;
light-emitting portions disposed on the pixel electrodes;
light-shielding portions disposed above the pixel defining layer; and
a color filter layer comprising a first color forming portion, a second color forming portion, and a third color forming portion, which are positioned above the light-emitting portions, wherein the first color forming portion, the second color forming portion, and the third color forming portion transmit lights of different colors,
wherein the first color forming portion, the second color forming portion and the third color forming portion comprise a first color filter, a second color filter and a third color filter, respectively,
wherein in the light-shielding portion, the first color filter, the second color filter, and the third color filter overlap one another in a thickness direction, and
wherein the smaller one of openings defined by the second color filter or the third color filter in a pixel corresponding to the first color forming portion has an area different from an area of the smaller one of openings defined by the first color filter or the third color filter in a pixel corresponding to the second color forming portion.

18. The display device according to claim 17, wherein the larger one of the openings defined by the second color filter or the third color filter in the pixel corresponding to the first color forming portion has an area different from an area of the larger one of the openings defined by the first color filter or the third color filter in the pixel corresponding to the second color forming portion.

19. An electronic device comprising:
a display device;
a memory; and
a processor which controls an operation of the display device by executing data included in the memory,
wherein the display device comprises:
a lower substrate;
pixel electrodes disposed on the lower substrate;
a pixel defining layer which defines pixels overlapping the pixel electrodes on the lower substrate;
light-emitting portions disposed on the pixel electrodes;
light-shielding portions disposed above the pixel defining layer; and
a color filter layer comprising a first color forming portion, a second color forming portion, and a third color forming portion, which are positioned above the light-emitting portions, wherein the first color forming portion, the second color forming portion, and the third color forming portion transmit lights of different colors,
wherein the first color forming portion, the second color forming portion and the third color forming portion comprise a first color filter, a second color filter and a third color filter, respectively,
wherein in the light-shielding portion, the first color filter, the second color filter, and the third color filter overlap one another in a thickness direction and
wherein a shorter separation distance between a point corresponding to an end of the pixel defining layer in the first color forming portion and either the second color filter or the third color filter of an adjacent light-shielding portion of the first color forming portion is different from a shorter separation distance between a point corresponding to an end of the pixel defining layer in the second color forming portion and either the first color filter or the third color filter of an adjacent light-shielding portion of the second color forming portion.

20. The electronic device according to claim 19, wherein the electronic device comprises virtual reality or augmented reality glasses, a smartphone, a tablet persona computer, a laptop computer, a television, a desk monitor, smart glasses, a head-mounted display, a smart watch, or a vehicle display.
